(19) United States
(12) Patent Application Publication
(10) Pub. No.: US 2026/0080130 A1
(43) Pub. Date: Mar. 19, 2026

(54) CARBON CYCLE MANAGEMENT

(71) Applicant: Schlumberger Technology Corporation, Sugar Land, TX (US)

(72) Inventors: Mohamed Osman Mahgoub Ahmed, Abu Dhabi (AE); Shi Su, Abu Dhabi (AE); Hussein Mustapha, Abu Dhabi (AE); Samat Ramatullayev, Abu Dhabi (AE)

(21) Appl. No.: 19/328,829

(22) Filed: Sep. 15, 2025

Related U.S. Application Data
(60) Provisional application No. 63/694,261, filed on Sep. 13, 2024.

(51) Int. Cl. G06F 30/27

(52) U.S. Cl. CPC G06F 30/27

(57) ABSTRACT

A method for tracking and mitigating greenhouse gases (GHG) in climate science and/or Earth systems modelling includes training a system to produce a trained system. The system is trained to track GHG emissions and/or flux. The method also includes receiving input data related to a situation at a site. The method also includes predicting one or more outputs using the trained system. The one or more outputs are predicted based upon the input data. The method also includes comparing decarbonization strategies based upon the one or more outputs. The method also includes recommending one of the decarbonization strategies to reduce the GHG emissions and/or flux in the situation at the site based upon the comparison.

### CROSS-REFERENCE TO RELATED APPLICATIONS

This application claims priority to and the benefit of U.S. Provisional Patent Application No. 63/694,261, filed on Sep. 13, 2024, which is incorporated by reference herein in its entirety.

### BACKGROUND

Climate change is a problem of carbon cycle imbalance. Human activities, particularly energy extraction, release carbon from the subsurface into the atmosphere at a rate that far exceeds the natural processes that return carbon to the Earth. Carbon sequestration offers a potential solution by helping to restore this balance and prevent dangerous levels of carbon dioxide (CO₂) accumulation in the atmosphere.

Currently, much of the focus is on modeling CO₂ movement within subsurface reservoirs, such as aquifers and depleted gas fields. This approach leverages the expertise developed in oil and gas reservoir modeling. However, effective carbon tracking involves extending these capabilities to new challenges, including simulating the migration of CO₂ from reservoirs to the surface, modeling its flow through shallow, unconsolidated sediments, and predicting bubble flow of CO₂ through the seabed into the atmosphere. To close the loop, comprehensive CO₂ tracking systems should also account for carbon capture, whether from the atmosphere via direct air capture or from industrial sources such as steel, cement, power plants, and blue hydrogen facilities.

Therefore, what is needed is an improved system and method for managing a carbon cycle. More particularly, the improved system and method should provide comprehensive CO₂ tracking by accounting for carbon capture.

### SUMMARY

A method for tracking and mitigating greenhouse gases (GHG) in climate science and/or Earth systems modelling is disclosed. The method includes training a system to produce a trained system. The system is trained to track GHG emissions and/or flux. The method also includes receiving input data related to a situation at a site. The method also includes predicting one or more outputs using the trained system. The one or more outputs are predicted based upon the input data. The method also includes comparing decarbonization strategies based upon the one or more outputs. The method also includes recommending one of the decarbonization strategies to reduce the GHG emissions and/or flux in the situation at the site based upon the comparison.

A computing system is also disclosed. The computing system includes one or more processors and a memory system. The memory system includes one or more non-transitory computer-readable media storing instructions that, when executed by at least one of the one or more processors, cause the computing system to perform operations. The operations include training a system to produce a trained system. The system includes a collaborative multi-agent system (MAS). The MAS includes different agents for different physics domains including an atmosphere model, an ocean model, a shallow surface model, a deep subsurface model, industrial and process plant digital twins, and/or subsurface models for applications including carbon sequestration, hydrocarbon production, geothermal reservoirs, underground gas storage, or a combination thereof. The system is trained to track GHG emissions and fluxes. The GHG comprises carbon dioxide and/or methane. The system is trained based upon simulation data and/or real-world measured data. The simulation data is derived from coupled atmospheric and energy process models, equations related to fluid flow in porous media, object-based modeling of fracture networks, or a combination thereof. The operations also include receiving input data related to a situation at a site. The input data includes contextual information about a subsurface of the site, a surface of the site, an industrial process being performed in the situation at the site, or a combination thereof. The input data is from different sources including atmospheric carbon dioxide records, satellite-based measurements, soil carbon data, micro-meteorological tower sites, vegetation indices, climate variables, or a combination thereof. The operations also include predicting one or more outputs based upon the input data using the trained system. The one or more outputs include an annual net carbon flux between an atmosphere and an ocean, the GHG emissions across different domains and/or sites, the fluxes across the different domains and/or sites, or a combination thereof. The operations also include comparing decarbonization strategies using the trained system based upon the one or more outputs. The decarbonization strategies reduce the GHG emissions and flux in the situation at the site. The operations also include recommending one of the decarbonization strategies to reduce the GHG emissions and flux in the situation at the site based upon the comparison.

A non-transitory computer-readable medium is also disclosed. The medium includes instructions that, when executed by one or more processors of a computing system, cause the computing system to perform operations. The operations include training a system to produce a trained system. The system incorporates multi-scale, multi-physics data-driven frameworks. The system is trained using generative artificial intelligence (Gen AI). The system includes a collaborative multi-agent system (MAS). The MAS includes different agents for different physics domains including an atmosphere model, an ocean model, a shallow surface model, a deep subsurface model, industrial and process plant digital twins, and subsurface models for applications including carbon sequestration, hydrocarbon production, geothermal reservoirs, and underground gas storage. The system is trained to track GHG emissions and fluxes. The GHG includes carbon dioxide and/or methane. The system is trained based upon simulation data and real-world measured data. The simulation data is derived from coupled atmospheric and energy process models, equations related to fluid flow in porous media, and object-based modeling of fracture networks. The training includes cataloging input parameters in different forms. The input parameters include structured grids and/or vectorized parameters. The training also includes performing edge case analysis to identify underrepresented distributions of the input parameters and incorporating edge cases to reduce extrapolation during inferences. The operations also include receiving input data related to a situation at a site. The input data includes contextual information about a subsurface of the site, a surface of the site, and an industrial process being performed in the situation at the site. The input data is from different sources including atmospheric carbon dioxide records, satellite-based measurements, soil carbon data, micro-meteorological tower sites, vegetation indices, and climate variables. The operations also include predicting one or more outputs based upon the input data using the trained system. The one or more outputs include an annual net carbon flux between an atmosphere and an ocean, the GHG emissions across different domains and/or sites, and the fluxes across the different domains and/or sites. The operations also include comparing decarbonization strategies using the trained system based upon the one or more outputs. The decarbonization strategies reduce the GHG emissions and flux in the situation at the site. The decarbonization strategies include: detecting and repairing GHG leaks; eliminating flaring and/or venting of the GHG; sequestering the GHG into saline aquifers and/or depleted hydrocarbon reservoirs; converting control and process equipment from gas to electric; modifying water and/or gas management strategies based on surface and/or subsurface insights; switching to green and/or blue hydrogen production; and/or upgrading the control and process equipment and/or field flow. The operations also include recommending one of the decarbonization strategies to reduce the GHG emissions and flux in the situation at the site based upon the comparison. The decarbonization strategy is also recommended based upon economic, environmental, and operational considerations.

It will be appreciated that this summary is intended merely to introduce some aspects of the present methods, systems, and media, which are more fully described and/or claimed below. Accordingly, this summary is not intended to be limiting.

### BRIEF DESCRIPTION OF THE DRAWINGS

The accompanying drawings, which are incorporated in and constitute a part of this specification, illustrate embodiments of the present teachings and together with the description, serve to explain the principles of the present teachings. In the figures:

FIG. 1 illustrates an example of a system that includes various management components to manage various aspects of a geologic environment, according to an embodiment.

FIG. 2 illustrates a flowchart of a method for tracking carbon dioxide (CO₂), according to an embodiment.

FIG. 3 illustrates a schematic view of a computing system for performing at least a portion of the method(s) described herein, according to an embodiment.

### DETAILED DESCRIPTION

Reference will now be made in detail to embodiments, examples of which are illustrated in the accompanying drawings and figures. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, components, circuits, and networks have not been described in detail so as not to unnecessarily obscure aspects of the embodiments.

It will also be understood that, although the terms first, second, etc. may be used herein to describe various elements, these elements should not be limited by these terms. These terms are only used to distinguish one element from another. For example, a first object or step could be termed a second object or step, and, similarly, a second object or step could be termed a first object or step, without departing from the scope of the present disclosure. The first object or step, and the second object or step, are both, objects or steps, respectively, but they are not to be considered the same object or step.

The terminology used in the description herein is for the purpose of describing particular embodiments and is not intended to be limiting. As used in this description and the appended claims, the singular forms “a,” “an” and “the” are intended to include the plural forms as well, unless the context clearly indicates otherwise. It will also be understood that the term “and/or” as used herein refers to and encompasses any possible combinations of one or more of the associated listed items. It will be further understood that the terms “includes,” “including,” “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. Further, as used herein, the term “if” may be construed to mean “when” or “upon” or “in response to determining”or “in response to detecting,”depending on the context.

Attention is now directed to processing procedures, methods, techniques, and workflows that are in accordance with some embodiments. Some operations in the processing procedures, methods, techniques, and workflows disclosed herein may be combined and/or the order of some operations may be changed.

### System Overview

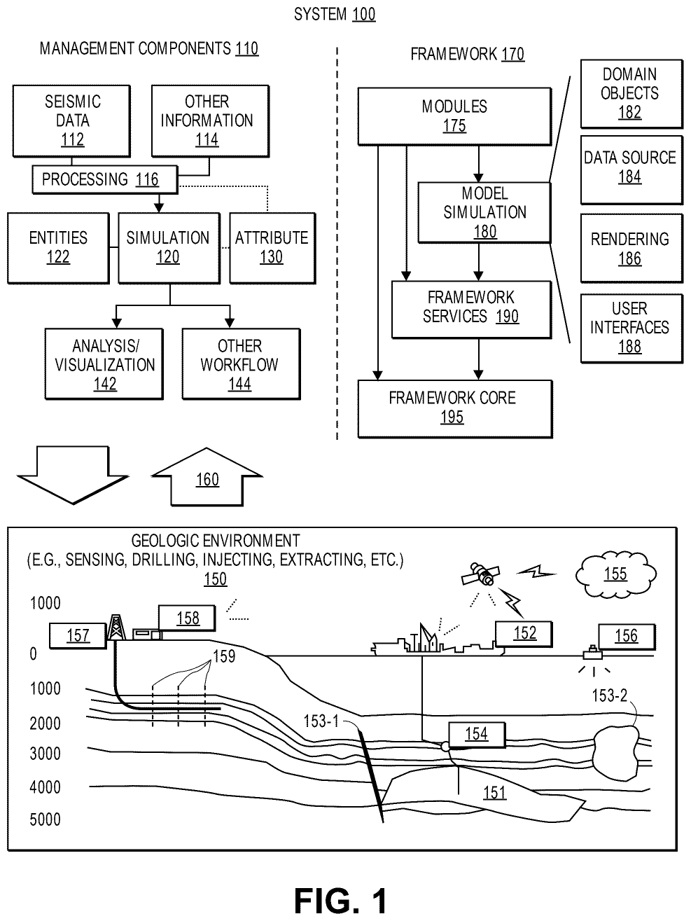

FIG. 1 illustrates an example of a system 100 that includes various management components 110 to manage various aspects of a geologic environment 150 (e.g., an environment that includes a sedimentary basin, a reservoir 151, one or more faults 153-1, one or more geobodies 153-2, etc.). For example, the management components 110 may allow for direct or indirect management of sensing, drilling, injecting, extracting, etc., with respect to the geologic environment 150. In turn, further information about the geologic environment 150 may become available as feedback 160 (e.g., optionally as input to one or more of the management components 110).

In the example of FIG. 1, the management components 110 include a seismic data component 112, an additional information component 114 (e.g., well/logging data), a processing component 116, a simulation component 120, an attribute component 130, an analysis/visualization component 142 and a workflow component 144. In operation, seismic data and other information provided per the components 112 and 114 may be input to the simulation component 120.

In an example embodiment, the simulation component 120 may rely on entities 122. Entities 122 may include earth entities or geological objects such as wells, surfaces, bodies, reservoirs, etc. In the system 100, the entities 122 can include virtual representations of actual physical entities that are reconstructed for purposes of simulation. The entities 122 may include entities based on data acquired via sensing, observation, etc. (e.g., the seismic data 112 and other information 114). An entity may be characterized by one or more properties (e.g., a geometrical pillar grid entity of an earth model may be characterized by a porosity property). Such properties may represent one or more measurements (e.g., acquired data), calculations, etc.

In an example embodiment, the simulation component 120 may operate in conjunction with a software framework such as an object-based framework. In such a framework, entities may include entities based on pre-defined classes to facilitate modeling and simulation. A commercially available example of an object-based framework is the MICROSOFT® .NET® framework (Redmond, Washington), which provides a set of extensible object classes. In the .NET® framework, an object class encapsulates a module of reusable code and associated data structures. Object classes can be used to instantiate object instances for use in by a program, script, etc. For example, borehole classes may define objects for representing boreholes based on well data.

In the example of FIG. 1, the simulation component 120 may process information to conform to one or more attributes specified by the attribute component 130, which may include a library of attributes. Such processing may occur prior to input to the simulation component 120 (e.g., consider the processing component 116). As an example, the simulation component 120 may perform operations on input information based on one or more attributes specified by the attribute component 130. In an example embodiment, the simulation component 120 may construct one or more models of the geologic environment 150, which may be relied on to simulate behavior of the geologic environment 150 (e.g., responsive to one or more acts, whether natural or artificial). In the example of FIG. 1, the analysis/visualization component 142 may allow for interaction with a model or model-based results (e.g., simulation results, etc.). As an example, output from the simulation component 120 may be input to one or more other workflows, as indicated by a workflow component 144.

As an example, the simulation component 120 may include one or more features of a simulator such as the ECLIPSE™ reservoir simulator (SLB, Houston Texas), the INTERSECT™ reservoir simulator (SLB, Houston Texas), etc. As an example, a simulation component, a simulator, etc. may include features to implement one or more meshless techniques (e.g., to solve one or more equations, etc.). As an example, a reservoir or reservoirs may be simulated with respect to one or more enhanced recovery techniques (e.g., consider a thermal process such as SAGD, etc.).

As an example, the simulation component 120 may include one or more features of a simulator such as SYMMETRY™ software (SLB, Houston, Texas). More particularly, SYMMETRY™ may process workflows in a single integrated environment with accurate thermodynamic fluid representation and consistent modeling across multiple disciplines including process, production, and HSE. The simulator integrates steady-state and transient (e.g., dynamic) analyses that can be tailored for each domain. This approach enables users to optimize processes in upstream, midstream, and downstream sectors while maximizing profits and minimizing capital expenditures. It may also help reduce emissions, energy consumption, and waste.

As an example, the simulation component 120 may include one or more features of a simulator such as PIPESIM™ (SLB, Houston, Texas). More particularly, PIPESIM™ is steady-state multiphase flow simulator that incorporates the three areas of flow modeling: multiphase flow, heat transfer and fluid behavior.

As an example, the simulation component 120 may include one or more features of a simulator such as OLGA™ (SLB, Houston, Texas). More particularly, OLGA™ is a dynamic multiphase flow simulator that models transient flow (e.g., time-dependent behaviors) to maximize production potential. Transient modeling is a component for feasibility studies and field development design. Dynamic simulation is useful in deep water and is used in both offshore and onshore developments to investigate transient behavior in pipelines and wellbores. Transient simulation with the OLGA™ simulator provides an added dimension to steady-state analysis by predicting system dynamics, such as time-varying changes in flow rates, fluid compositions, temperature, solids deposition, and operational changes.

In an example embodiment, the management components 110 may include features of a commercially available framework such as the PETREL® seismic to simulation software framework (SLB, Houston, Texas). The PETREL® framework provides components that allow for optimization of exploration and development operations. The PETREL® framework includes seismic to simulation software components that can output information for use in increasing reservoir performance, for example, by improving asset team productivity. Through use of such a framework, various professionals (e.g., geophysicists, geologists, and reservoir engineers) can develop collaborative workflows and integrate operations to streamline processes. Such a framework may be considered an application and may be considered a data-driven application (e.g., where data is input for purposes of modeling, simulating, etc.).

In an example embodiment, various aspects of the management components 110 may include add-ons or plug-ins that operate according to specifications of a framework environment. For example, a commercially available framework environment marketed as the OCEAN® framework environment (SLB, Houston, Texas) allows for integration of add-ons (or plug-ins) into a PETREL® framework workflow. The OCEAN® framework environment leverages .NET® tools (Microsoft Corporation, Redmond, Washington) and offers stable, user-friendly interfaces for efficient development. In an example embodiment, various components may be implemented as add-ons (or plug-ins) that conform to and operate according to specifications of a framework environment (e.g., according to application programming interface (API) specifications, etc.).

FIG. 1 also shows an example of a framework 170 that includes a model simulation layer 180 along with a framework services layer 190, a framework core layer 195 and a modules layer 175. The framework 170 may include the commercially available OCEAN® framework where the model simulation layer 180 is the commercially available PETREL® model-centric software package that hosts OCEAN® framework applications. In an example embodiment, the PETREL® software may be considered a data-driven application. The PETREL® software can include a framework for model building and visualization.

As an example, a framework may include features for implementing one or more mesh generation techniques. For example, a framework may include an input component for receipt of information from interpretation of seismic data, one or more attributes based at least in part on seismic data, log data, image data, etc. Such a framework may include a mesh generation component that processes input information, optionally in conjunction with other information, to generate a mesh.

In the example of FIG. 1, the model simulation layer 180 may provide domain objects 182, act as a data source 184, provide for rendering 186 and provide for various user interfaces 188. Rendering 186 may provide a graphical environment in which applications can display their data while the user interfaces 188 may provide a common look and feel for application user interface components.

As an example, the domain objects 182 can include entity objects, property objects and optionally other objects. Entity objects may be used to geometrically represent wells, surfaces, bodies, reservoirs, etc., while property objects may be used to provide property values as well as data versions and display parameters. For example, an entity object may represent a well where a property object provides log information as well as version information and display information (e.g., to display the well as part of a model).

In the example of FIG. 1, data may be stored in one or more data sources (or data stores, generally physical data storage devices), which may be at the same or different physical sites and accessible via one or more networks. The model simulation layer 180 may be configured to model projects. As such, a particular project may be stored where stored project information may include inputs, models, results and cases. Thus, upon completion of a modeling session, a user may store a project. At a later time, the project can be accessed and restored using the model simulation layer 180, which can recreate instances of the relevant domain objects.

In the example of FIG. 1, the geologic environment 150 may include layers (e.g., stratification) that include a reservoir 151 and one or more other features such as the fault 153-1, the geobody 153-2, etc. As an example, the geologic environment 150 may be outfitted with any of a variety of sensors, detectors, actuators, etc. For example, equipment 152 may include communication circuitry to receive and to transmit information with respect to one or more networks 155. Such information may include information associated with downhole equipment 154, which may be equipment to acquire information, to assist with resource recovery, etc. Other equipment 156 may be located remote from a well site and include sensing, detecting, emitting or other circuitry. Such equipment may include storage and communication circuitry to store and to communicate data, instructions, etc. As an example, one or more satellites may be provided for purposes of communications, data acquisition, etc. For example, FIG. 1 shows a satellite in communication with the network 155 that may be configured for communications, noting that the satellite may additionally or instead include circuitry for imagery (e.g., spatial, spectral, temporal, radiometric, etc.).

FIG. 1 also shows the geologic environment 150 as optionally including equipment 157 and 158 associated with a well that includes a substantially horizontal portion that may intersect with one or more fractures 159. For example, consider a well in a shale formation that may include natural fractures, artificial fractures (e.g., hydraulic fractures) or a combination of natural and artificial fractures. As an example, a well may be drilled for a reservoir that is laterally extensive. In such an example, lateral variations in properties, stresses, etc. may exist where an assessment of such variations may assist with planning, operations, etc. to develop a laterally extensive reservoir (e.g., via fracturing, injecting, extracting, etc.). As an example, the equipment 157 and/or 158 may include components, a system, systems, etc. for fracturing, seismic sensing, analysis of seismic data, assessment of one or more fractures, etc.

As mentioned, the system 100 may be used to perform one or more workflows. A workflow may be a process that includes a number of worksteps. A workstep may operate on data, for example, to create new data, to update existing data, etc. As an example, a may operate on one or more inputs and create one or more results, for example, based on one or more algorithms. As an example, a system may include a workflow editor for creation, editing, executing, etc. of a workflow. In such an example, the workflow editor may provide for selection of one or more pre-defined worksteps, one or more customized worksteps, etc. As an example, a workflow may be a workflow implementable in the PETREL® software, for example, that operates on seismic data, seismic attribute(s), etc. As an example, a workflow may be a process implementable in the OCEAN® framework. As an example, a workflow may include one or more worksteps that access a module such as a plug-in (e.g., external executable code, etc.).

### Carbon Cycle Management

To effectively track carbon throughout its lifecycle, the method described herein integrates multiple modeling workflows at various scales. For instance, an invasion percolation (IP) model may yield results in capturing the movement of CO₂ plumes. To enhance accuracy, the physics of CO₂ migration at different scales may be incorporated into upscaled models. Thus, the method uses a multi-physics and multi-scale framework that combines data-driven insights to track CO₂ through every stage: in controlled atmospheric volumes, in the ocean, through shallow sediments, in open subsurface flows, in saline aquifer and depleted reservoirs, or a combination thereof.

The method may leverage the power of generative artificial intelligence (Gen AI) and multi-agent systems (MAS) to provide a hybrid multi-scale multi-physics and data-driven framework to track CO₂ within a controlled volume in the atmosphere and in the subsurface. The individual components of the method are physics and data-driven representations of CO₂ behavior in different situations, as outlined below.

More particularly, the method may perform a physics-based evaluation and/or data-driven representation of CO₂ sequestration in sealed saline aquifers and depleted reservoirs based upon a finite difference/volume solution of the diffusivity equation (e.g., viscous, capillary, and gravity). The method may also perform physics-based simulations based on the principle of invasion percolation (IP) that are better suited for long term capillary-gravity related flow. The method may also perform direct modeling and/or pore network modeling of CO₂ in porous media to capture multi-phase flow simulation effects. The method may also produce constitutive relationships such as relative permeability and capillary pressure functions of saturation values and/or saturation paths.

The method may also perform a geochemistry evaluation of solid particles precipitation as a result of CO₂ injection in different rock types, and the long-term trapping and mineralization of CO₂ at different conditions. The method may also simulate CO₂ hydrate formation and its utilization in CO₂ capture and impact on surface and subsurface flow of CO₂. The method may also perform simulations and/or data-driven representation of flow of CO₂ in pipes (e.g., well, surface networks, etc.). The method may also perform simulations and/or data-driven representation of DAC stations and industrial production plants. The method may also perform simulations and/or data-driven representation of flow in open subsurface and shallow sediments.

The method may also perform bubble flow of CO₂ in water. The method may also include or simulate climate models with various species including CO₂. The method may also include or provide the capability to appraise grid power capacity and the opportunity to connect to it. The method may also perform a physics and data-based evaluation of geothermal power (e\.g., shallow and/or deep) utilization and its impact on carbon footprint. The method may also perform a physics and data-based evaluation of solar power (PV/heat) utilization and its impact on carbon footprint.

These solutions can be managed by MAS in a swarm intelligence approach with the purpose of holistic tracking of CO₂ within the selected control volume. Thus, the method can provide accurate predictions of CO₂ reduction given a specific action. The system can also recommend effective actions a customer can take to reduce carbon emissions.

The method may evaluate carbon equivalent emissions in reservoir simulation field development planning scenarios to optimize field development plan on hydrocarbon production, economics, and carbon emissions. The method may also or instead calculate and estimate carbon equivalent emissions based on reservoir simulation field development plan configurations (e.g., well count, well length, etc.) and reservoir simulation results (e.g., hydrocarbon/water production and injection). The method may forecast emissions alongside production using a machine learning proxy model

### Exemplary Method

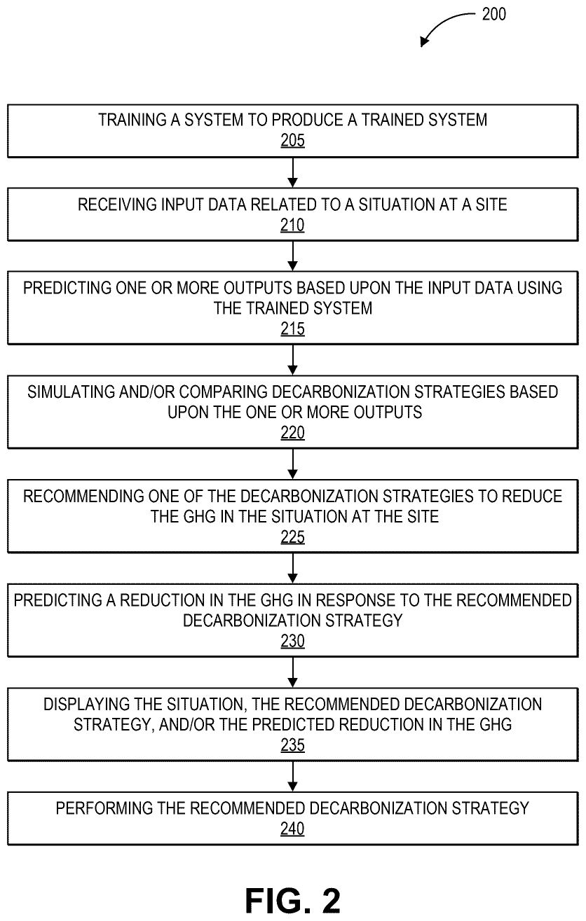

FIG. 2 illustrates a flowchart of a method 200 for tracking and mitigating greenhouse gases (GHG), according to an embodiment. The method 200 may be used in (or part of) climate science and/or Earth systems modelling. An illustrative order of the method 200 is provided below; however, one or more portions of the method 200 may be performed in a different order, simultaneously, repeated, or omitted. At least a portion of the method 200 may be performed using a computing system.

The method 200 may include training a system to produce a trained system, as at 205. The system may incorporate multi-scale and/or multi-physics data-driven frameworks. The system may be trained using generative artificial intelligence (Gen AI). The system may include a collaborative multi-agent system (MAS). More particularly, the MAS may include different agents for different physics domains including an atmosphere model, an ocean model, a shallow surface model, a deep subsurface model, industrial and process plant digital twins, subsurface models, or a combination thereof. The different physics domains (e.g., the subsurface models) may be used for applications including carbon sequestration, hydrocarbon production, geothermal reservoirs, underground gas storage, or a combination thereof. The system may be trained to track GHG emissions and/or fluxes. The GHG may be or include carbon dioxide and/or methane. The GHG flux refers to the movement of GHG between the atmosphere and various ecosystems.

The system may be trained based upon simulation data and/or real-world measured data. The simulation data may be derived from coupled atmospheric and energy process models, equations related to fluid flow in porous media, object-based modeling of fracture networks, or a combination thereof. In an embodiment, the training may include cataloging input parameters in different forms. The input parameters may be or include structured grids and/or vectorized parameters. The training may also or instead include performing edge case analysis to identify underrepresented distributions of the input parameters and incorporating edge cases to reduce extrapolation during inferences.

The method 200 may also include receiving input data, as at 210. The input data may be related to a situation and/or a site. In an example, the site may include a location of a wellsite, an oil and gas processing facility/plant, or both. The input data may include contextual information about a subsurface of the site, a surface of the site, an industrial process (e.g., drilling, completion, production, refinement, etc.) being performed in the situation at the site, or a combination thereof. For example, the input data may be from different sources including atmospheric carbon dioxide records, satellite-based measurements, soil carbon data, micro-meteorological tower sites, vegetation indices, climate variables, or a combination thereof. In an embodiment, the system may also be trained at least partially based upon the input data.

The method 200 may also include predicting one or more outputs based upon the input data using the trained system, as at 215. The one or more outputs may include an (e.g., annual) net carbon flux between an atmosphere and an ocean, the GHG emissions across different domains and/or sites, the fluxes across the different domains and/or sites, or a combination thereof. Examples of the different physics domains are provided above.

The method 200 may also include simulating and/or comparing decarbonization strategies, as at 220. The decarbonization strategies may be simulated and/or compared using the trained system. The decarbonization strategies may also or instead be simulated and/or compared based upon the input data and/or the one or more outputs. The decarbonization strategies may reduce the GHG and/or fluxes in the situation at the selected site. The decarbonization strategies may include detecting and repairing GHG leaks. The decarbonization strategies may also or instead include eliminating flaring and/or venting of the GHG. The decarbonization strategies may also or instead include sequestering the GHG into saline aquifers and/or depleted hydrocarbon reservoirs. The decarbonization strategies may also or instead include converting control and process equipment from gas to electric. The decarbonization strategies may also or instead include modifying water and/or gas management strategies based on surface and/or subsurface insights. The decarbonization strategies may also or instead include switching to green and/or blue hydrogen production. The decarbonization strategies may also or instead include upgrading the control and process equipment and/or field flow.

The method 200 may also include recommending one of the decarbonization strategies to reduce the GHG emissions and/or flux in the situation at the site, as at 225. The recommendation may be based upon the comparison. The recommendation may also be based upon economic, environmental, and/or operational considerations.

The method 200 may also include predicting a reduction in the GHG emissions and/or flux in response to the recommended decarbonization strategy, as at 230.

The method 200 may also include displaying the situation, the recommended decarbonization strategy, and/or the predicted reduction in the GHG emissions and/or flux, as at 235.

The method 200 may also include performing the recommended decarbonization strategy, as at 240. In an embodiment, performing the recommended decarbonization strategy may include generating and/or transmitting a signal that recommends, instructs, or causes the recommended decarbonization strategy to be performed and/or implemented. In another embodiment, performing the recommended decarbonization strategy may include physically performing and/or implementing the recommended decarbonization strategy.

### Exemplary Computing System

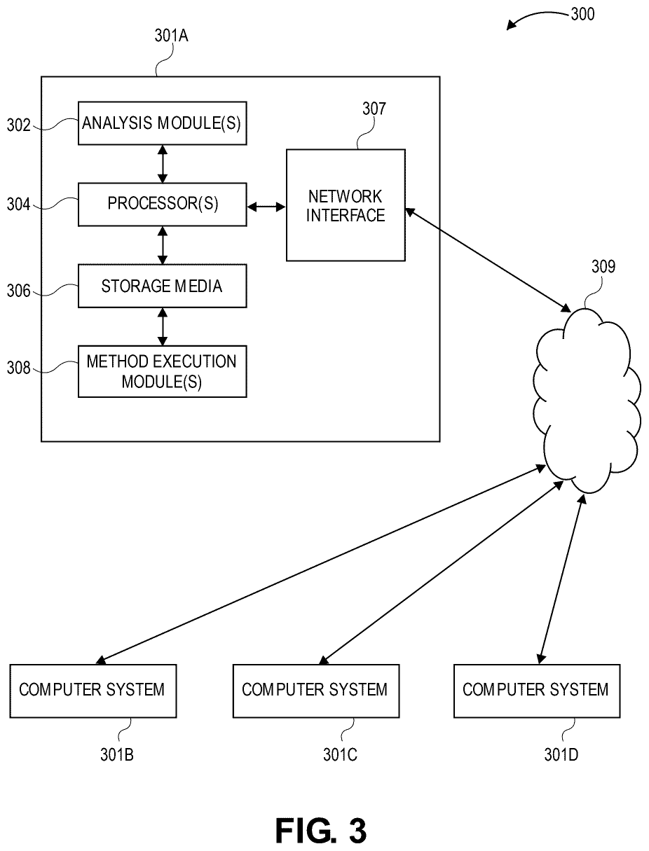

In some embodiments, the methods of the present disclosure may be executed by a computing system. FIG. 3 illustrates an example of such a computing system 300, in accordance with some embodiments. The computing system 300 may include a computer or computer system 301A, which may be an individual computer system 301A or an arrangement of distributed computer systems. The computer system 301A includes one or more analysis modules 302 that are configured to perform various tasks according to some embodiments, such as one or more methods disclosed herein. To perform these various tasks, the analysis module 302 executes independently, or in coordination with, one or more processors 304, which is (or are) connected to one or more storage media 306. The processor(s) 304 is (or are) also connected to a network interface 307 to allow the computer system 301A to communicate over a data network 309 with one or more additional computer systems and/or computing systems, such as 301B, 301C, and/or 301D (note that computer systems 301B, 301C and/or 301D may or may not share the same architecture as computer system 301A, and may be located in different physical locations, e.g., computer systems 301A and 301B may be located in a processing facility, while in communication with one or more computer systems such as 301C and/or 301D that are located in one or more data centers, and/or located in varying countries on different continents).

A processor may include a microprocessor, microcontroller, processor module or subsystem, programmable integrated circuit, programmable gate array, or another control or computing device.

The storage media 306 may be implemented as one or more computer-readable or machine-readable storage media. Note that while in the example embodiment of FIG. 3 storage media 306 is depicted as within computer system 301A, in some embodiments, storage media 306 may be distributed within and/or across multiple internal and/or external enclosures of computing system 301A and/or additional computing systems. Storage media 306 may include one or more different forms of memory including semiconductor memory devices such as dynamic or static random access memories (DRAMs or SRAMs), erasable and programmable read-only memories (EPROMs), electrically erasable and programmable read-only memories (EEPROMs) and flash memories, magnetic disks such as fixed, floppy and removable disks, other magnetic media including tape, optical media such as compact disks (CDs) or digital video disks (DVDs), BLURAY® disks, or other types of optical storage, or other types of storage devices. Note that the instructions discussed above may be provided on one computer-readable or machine-readable storage medium, or may be provided on multiple computer-readable or machine-readable storage media distributed in a large system having possibly plural nodes. Such computer-readable or machine-readable storage medium or media is (are) considered to be part of an article (or article of manufacture). An article or article of manufacture may refer to any manufactured single component or multiple components. The storage medium or media may be located either in the machine running the machine-readable instructions, or located at a remote site from which machine-readable instructions may be downloaded over a network for execution.

In some embodiments, computing system 300 contains one or more method execution module(s) 308. In the example of computing system 300, computer system 301A includes the method execution module 308. In some embodiments, a single method execution module may be used to perform some aspects of one or more embodiments of the methods disclosed herein. In other embodiments, a plurality of method execution modules may be used to perform some aspects of methods herein.

It should be appreciated that computing system 300 is merely one example of a computing system, and that computing system 300 may have more or fewer components than shown, may combine additional components not depicted in the example embodiment of FIG. 3, and/or computing system 300 may have a different configuration or arrangement of the components depicted in FIG. 3. The various components shown in FIG. 3 may be implemented in hardware, software, or a combination of both hardware and software, including one or more signal processing and/or application specific integrated circuits.

Further, the steps in the processing methods described herein may be implemented by running one or more functional modules in information processing apparatus such as general purpose processors or application specific chips, such as ASICs, FPGAs, PLDs, or other appropriate devices. These modules, combinations of these modules, and/or their combination with general hardware are included within the scope of the present disclosure.

Computational interpretations, models, and/or other interpretation aids may be refined in an iterative fashion; this concept is applicable to the methods discussed herein. This may include use of feedback loops executed on an algorithmic basis, such as at a computing device (e.g., computing system 300, FIG. 3), and/or through manual control by a user who may make determinations regarding whether a given step, action, template, model, or set of curves has become sufficiently accurate for the evaluation of the subsurface three-dimensional geologic formation under consideration.

The foregoing description, for purpose of explanation, has been described with reference to specific embodiments. However, the illustrative discussions above are not intended to be exhaustive or limiting to the precise forms disclosed. Many modifications and variations are possible in view of the above teachings. Moreover, the order in which the elements of the methods described herein are illustrated and described may be re-arranged, and/or two or more elements may occur simultaneously. The embodiments were chosen and described in order to best explain the principles of the disclosure and its practical applications, to thereby enable others skilled in the art to best utilize the disclosed embodiments and various embodiments with various modifications as are suited to the particular use contemplated.

What is claimed is:

1. A method for tracking and mitigating greenhouse gases (GHG) in climate science and/or Earth systems modelling, the method comprising:
training a system to produce a trained system, wherein the system is trained to track GHG emissions and/or flux;
receiving input data related to a situation at a site;
predicting one or more outputs using the trained system, wherein the one or more outputs are predicted based upon the input data;
comparing decarbonization strategies based upon the one or more outputs; and
recommending one of the decarbonization strategies to reduce the GHG emissions and/or flux in the situation at the site based upon the comparison.

2. The method of claim 1, wherein the system incorporates multi-scale, multi-physics data-driven frameworks, and wherein the system is trained using generative artificial intelligence (Gen AI).

3. The method of claim 1, wherein the system comprises a collaborative multi-agent system (MAS), and wherein the MAS comprises different agents for different physics domains including an atmosphere model, an ocean model, a shallow surface model, a deep subsurface model, industrial and process plant digital twins, and/or subsurface models for applications including carbon sequestration, hydrocarbon production, geothermal reservoirs, underground gas storage, or a combination thereof.

4. The method of claim 1, wherein the system is trained based upon simulation data and real-world measured data, and wherein the simulation data is derived from coupled atmospheric and energy process models, equations related to fluid flow in porous media, object-based modeling of fracture networks, or a combination thereof.

5. The method of claim 1, wherein the input data comprises contextual information about a subsurface of the site, a surface of the site, an industrial process being performed in the situation at the site, or a combination thereof.

6. The method of claim 1, wherein the input data is from different sources including atmospheric carbon dioxide records, satellite-based measurements, soil carbon data, micro-meteorological tower sites, vegetation indices, climate variables, or a combination thereof.

7. The method of claim 1, wherein the one or more outputs comprise an annual net carbon flux between an atmosphere and an ocean, the GHG emissions across different domains and/or sites, the flux across the different domains and/or sites, or a combination thereof.

8. The method of claim 1, wherein the decarbonization strategies reduce the GHG emissions and flux in the situation at the site.

9. The method of claim 1, further comprising displaying the one or more outputs and the recommended decarbonization strategy.

10. The method of claim 1, further comprising physically performing the recommended decarbonization strategy.

11. A computing system, comprising:
one or more processors; and
a memory system comprising one or more non-transitory computer-readable media storing instructions that, when executed by at least one of the one or more processors, cause the computing system to perform operations, the operations comprising:
training a system to produce a trained system, wherein the system comprises a collaborative multi-agent system (MAS), wherein the MAS comprises different agents for different physics domains, and wherein the system is trained to track greenhouse gas (GHG) emissions and fluxes;
receiving input data related to a situation at a site, wherein the input data comprises contextual information about a subsurface of the site, a surface of the site, an industrial process being performed in the situation at the site, or a combination thereof, and wherein the input data is from different sources including atmospheric carbon dioxide records, satellite-based measurements, soil carbon data, micro-meteorological tower sites, vegetation indices, climate variables, or a combination thereof;
predicting one or more outputs based upon the input data using the trained system, wherein the one or more outputs comprise an annual net carbon flux between an atmosphere and an ocean, the GHG emissions across different domains and/or sites, the fluxes across the different domains and/or sites, or a combination thereof;
comparing decarbonization strategies using the trained system based upon the one or more outputs, wherein the decarbonization strategies reduce the GHG emissions and flux in the situation at the site; and
recommending one of the decarbonization strategies to reduce the GHG emissions and flux in the situation at the site based upon the comparison.

12. The computing system of claim 11, wherein the training includes cataloging input parameters in different forms, and wherein the input parameters comprise structured grids and/or vectorized parameters.

13. The computing system of claim 11, wherein the training includes performing edge case analysis to identify underrepresented distributions of the input parameters and incorporating edge cases to reduce extrapolation during inferences.

14. The computing system of claim 11, wherein the decarbonization strategies comprise:
detecting and repairing GHG leaks;
eliminating flaring and/or venting of the GHG;
sequestering the GHG into saline aquifers and/or depleted hydrocarbon reservoirs;
converting control and process equipment from gas to electric;
modifying water and/or gas management strategies based on surface and/or subsurface insights;
switching to green and/or blue hydrogen production; and/or
upgrading the control and process equipment and/or field flow.

15. The computing system of claim 11, wherein the decarbonization strategy is also recommended based upon economic, environmental, and operational considerations.

16. A non-transitory computer-readable medium storing instructions that, when executed by one or more processors of a computing system, cause the computing system to perform operations, the operations comprising:
training a system to produce a trained system, wherein the system incorporates multi-scale, multi-physics data-driven frameworks, wherein the system is trained using generative artificial intelligence (Gen AI), wherein the system comprises a collaborative multi-agent system (MAS), wherein the MAS comprises different agents for different physics domains including an atmosphere model, an ocean model, a shallow surface model, a deep subsurface model, industrial and process plant digital twins, and subsurface models for applications including carbon sequestration, hydrocarbon production, geothermal reservoirs, and underground gas storage, wherein the system is trained to track greenhouse gas (GHG) emissions and fluxes, wherein the GHG comprises carbon dioxide and/or methane, wherein the system is trained based upon simulation data and real-world measured data, wherein the simulation data is derived from coupled atmospheric and energy process models, equations related to fluid flow in porous media, and object-based modeling of fracture networks, and wherein the training includes:
cataloging input parameters in different forms, wherein the input parameters comprise structured grids and/or vectorized parameters; and
performing edge case analysis to identify underrepresented distributions of the input parameters and incorporating edge cases to reduce extrapolation during inferences;
receiving input data related to a situation at a site, wherein the input data comprises contextual information about a subsurface of the site, a surface of the site, and an industrial process being performed in the situation at the site, and wherein the input data is from different sources including atmospheric carbon dioxide records, satellite-based measurements, soil carbon data, micro-meteorological tower sites, vegetation indices, and climate variables;
predicting one or more outputs based upon the input data using the trained system, wherein the one or more outputs comprise an annual net carbon flux between an atmosphere and an ocean, the GHG emissions across different domains and/or sites, and the fluxes across the different domains and/or sites;
comparing decarbonization strategies using the trained system based upon the one or more outputs, wherein the decarbonization strategies reduce the GHG emissions and flux in the situation at the site, and wherein the decarbonization strategies comprise:
detecting and repairing GHG leaks;
eliminating flaring and/or venting of the GHG;
sequestering the GHG into saline aquifers and/or depleted hydrocarbon reservoirs;
converting control and process equipment from gas to electric;
modifying water and/or gas management strategies based on surface and/or subsurface insights;
switching to green and/or blue hydrogen production; and/or
upgrading the control and process equipment and/or field flow; and
recommending one of the decarbonization strategies to reduce the GHG emissions and flux in the situation at the site based upon the comparison, wherein the decarbonization strategy is also recommended based upon economic, environmental, and operational considerations.

17. The non-transitory computer-readable medium of claim 16, wherein the operations further comprise predicting a reduction in the GHG emissions and flux in response to the recommended decarbonization strategy.

18. The non-transitory computer-readable medium of claim 17, wherein the operations further comprise displaying the recommended decarbonization strategy and the predicted reduction in the GHG emissions and flux.

19. The non-transitory computer-readable medium of claim 16, wherein the operations further comprise performing the recommended decarbonization strategy.

20. The non-transitory computer-readable medium of claim 19, wherein performing the recommended decarbonization strategy comprises generating and transmitting a signal that instructs or causes the recommended decarbonization strategy to be physically performed.
